(19) United States
(12) Patent Application Publication
(10) Pub. No.: US 2022/0108965 A1
(43) Pub. Date: Apr. 7, 2022

(54) LOW TEMPERATURE, REWORKABLE, AND NO-UNDERFILL ATTACH PROCESS FOR FINE PITCH BALL GRID ARRAYS HAVING SOLDER BALLS WITH EPOXY AND SOLDER MATERIAL

(71) Applicant: JABIL INC., St. Petersburg, FL (US)

(72) Inventors: Anwar A. Mohammed, St. Petersburg, FL (US); Harpuneet Singh, St. Petersburg, FL (US)

(21) Appl. No.: 17/314,356

(22) Filed: May 7, 2021

Related U.S. Application Data
(60) Provisional application No. 63/087,953, filed on Oct. 6, 2020.

(51) Int. Cl. H01L 23/00; H01L 23/498; H01L 21/50

(52) U.S. Cl. CPC H01L 24/14; H01L 23/49816; H01L 2021/60135; H01L 21/50; H01L 23/49838

(57) ABSTRACT

A ball grid array (BGA) including at least one BGA chip and a plurality of solder balls directly connected to a substrate, such as a printed circuit board (PCB), where the solder balls include an epoxy. A method for producing a BGA package including providing a BGA having a plurality of epoxy-containing solder balls, positioning the BGA on a substrate, such as a PCB, and applying heat to reflow the epoxy-containing solder balls and to create a connection between the BGA and the PCB.

### CROSS-REFERENCE TO RELATED APPLICATIONS

This application claims the benefit of the filing date of U.S. Provisional Application No. 63/087,953 titled, Low Temperature, Reworkable, And No-Underfill Attach Process For Fine Pitch Ball Grid Arrays, filed Oct. 6, 2020.

### BACKGROUND

### Field

The present disclosure relates generally to the field of surface mount packaging, and more particularly to surface mount packaging including a ball grid array (BGA).

### Discussion

This section provides background information related to the present disclosure which is not necessarily prior art.

Electronics manufacturers are increasingly using ball grid array (BGA) techniques for surface mount packaging of integrated circuits (IC). Because BGA packaging places soldered connections on the bottom side of the IC, or other component, using a BGA technique to connect an integrated circuit, or other component, to a printed circuit board (PCB) provides more interconnection pins than other attachment methods that place connections around the perimeter of an IC.

Warpage is one drawback to using a BGA technique for mounting an IC, or other component, to a PCB. Warpage tends to occur during the solder reflow step, which typically occurs at approximately 260° C. The high temperature in this step can result in thermo-mechanical stresses that can cause the IC to warp, i.e., become non-planar or non-flat. Because of the high potential for warpage, especially at the corners of the IC, corner-bonding is typically required. Additionally, underfill is commonly employed to redistribute stresses across the IC. Underfilling involves injecting an epoxy mixture under a component after it is soldered to the PCB, thereby essentially adhering the component to the PCB. Underfilling becomes more and more critical as the size of the BGA and/or the IC become larger. Underfilling and corner-bonding are extra costs for a BGA packager, and also prevent the BGA package from being reworked if the BGA package does not meet product specifications, for example. It is difficult to rework the BGA package when underfilling has been used because the PCB, the underfilling, and the IC are strongly adhered to one another.

In addition to a trend towards larger BGA packages, there is an industry trend towards fine pitch BGA packages, meaning the space between the BGA connections is becoming smaller and smaller. The density (distance between connections) is limited by the tendency for electrical shorting to occur when the BGA connections are too close together.

While the BGA packaging has shown to be an effective technology for attaching components to PCBs, there is a need in the art for a packing process for a BGA that has minimal warping, does not require underfilling, and allows for very fine pitch without causing electrical shorts.

### SUMMARY

The disclosed exemplary apparatuses, systems and methods can be utilized to provide a low temperature, reworkable, and no underfilling attachment process for fine pitch BGAs.

In one embodiment of the disclosure, a BGA comprises at least one component, such as at least one PCB pad, and at least one solder ball, where the at least one solder ball is directly connected to the at least one PCB pad and where the at least one solder ball includes an epoxy.

A method for producing a BGA package is disclosed. The method includes providing at least one BGA having at least one epoxy-containing solder ball, positioning the at least one BGA on a substrate, such as a PCB, and applying heat to reflow the at least one epoxy-containing solder ball and to create a connection between the at least one BGA and the PCB.

### BRIEF DESCRIPTION OF THE DRAWINGS

The disclosed non-limiting embodiments are discussed in relation to the drawings appended hereto and forming part hereof, wherein like numerals indicate like elements, and in which:

FIG. 1 is a front elevational view of a ball grid array (BGA) package during a positioning step;

FIG. 2 is a front elevational view of the BGA package of FIG. 1 during a reflow step;

FIG. 3 is a schematic flow diagram depicting a method for producing the BGA package of FIGS. 1 and 2; and

FIG. 4 is a schematic flow diagram depicting a method for producing a PCB assembly including the BGA package of FIGS. 1-3.

### DETAILED DESCRIPTION

The following detailed description and appended drawings describe and illustrate various embodiments of the disclosure. The description and drawings serve to enable one skilled in the art to make and use the disclosure, and are not intended to limit the scope of the disclosure in any manner. In respect of the methods disclosed, the steps presented are exemplary in nature, and thus, the order of the steps is not necessary or critical.

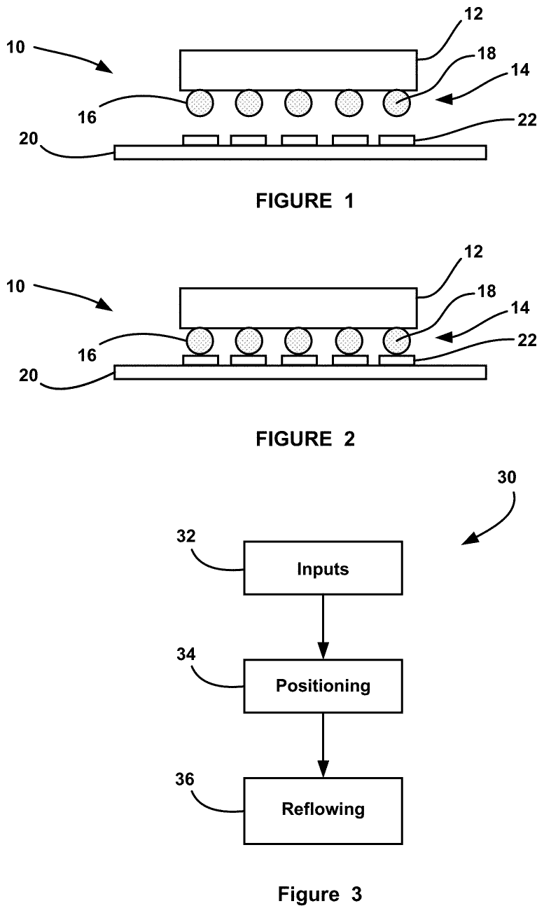

FIG. 1 is a front elevational view of a ball grid array (BGA) package 10. The BGA package 10 includes an electrical device 12, such as an integrated circuit, die or other component, and a two-dimensional BGA 14 including solder balls 16 having a certain diameter and a certain spacing, i.e., pitch, extending from an underside of the device 12. The solder balls 16 may be produced from a tin-bismuth based solder, which may be varied to obtain a desired reflow temperature, and may also include a self-aligning solder. The solder balls 16 include an electrically insulating epoxy 18 that may coat the solder balls 16 as an outer layer, be mixed into the solder balls 16, or may be both mixed into the solder balls 16 and coat and electrically insulate the solder balls 16, as desired. The solder balls 16 may also be formed from any material as desired, such as a powdered solder, a flux material, and an epoxy mixture, or other material having desired properties. The BGA package 10 also includes a printed circuit board (PCB) 20 on which is electrically mounted a series of solder pads 22, where a separate solder pad 22 is aligned with each of the solder balls 16. It is noted that although the BGA 14 is shown electrically coupled to the PCB 20 in this embodiment, this is by way of a non-limiting example. The BGA 14 can be electrically coupled to other ceramic and non-ceramic substrates, such as aluminum nitride, beryllium oxide, silicon carbide, etc. substrates.

FIG. 1 shows the BGA package 10 in a positioning step before the solder balls 16 are soldered to the pads 22. FIG. 2 shows the BGA package 10 in a reflow step where the solder balls 16 are soldered to the pads 22. During the reflow step, heat is provided to cause the solder balls 16 to become molten and expand, thereby creating strong connections between the device 12, the solder balls 16 and the pads 22. Because the solder balls 16 include the epoxy 18, the solder balls 16 and resulting interconnection pins are stronger and more flexible compared to solder balls without epoxy, which reduces the propensity for shorting because the solder balls 16 and resulting solder connections are surrounded by the epoxy 18, thereby creating a protective and electrically insulating layer. Further, the solder connections that are formed from the reflow step are less prone to electrical shorting (lateral shorting) compared to solder connections that do not include epoxy. The epoxy 18 offers a mechanical adhesion to the pads 22, which increases an attachment strength of the BGA 14 to the PCB 20.

The solder balls 16 including the epoxy 18 enable production of large scale BGAs, i.e., BGAs larger than 80 mm by 80 mm, where thermal warpage is minimized. The large scale BGAs can be produced, where the BGAs are able to pass thermal reliability testing without experiencing micro-cracking or fatigue failure. The reduced propensity for electrical shorting is advantageous when manufacturing a fine pitch BGA, where a fine pitch BGA is a BGA where solder connections (also referred to as interconnecting pins) are in close proximity to each other. For example, when the distance from a center of one of the solder balls 16 to a center of an adjacent one of the solder balls 16 may be 0.5 mm or less in a fine pitch BGA. Disclosed embodiments may include a fine pitch BGA arrangement of less than 0.5 mm between adjacent solder balls, measured center to center, or a non-fine pitch BGA arrangement of greater than 0.5 mm between adjacent solder balls, measured center to center. Alternatively, disclosed embodiments may include both a fine pitch arrangement and a non-fine pitch arrangement.

The reflow temperature for the solder balls 16 may be 200° C. or less. In another embodiment, the reflow temperature for the solder balls 16 may be between 140° C. and 190° C. These reflow temperatures are much lower than known reflow temperatures. Advantageously, at these lower reflow temperatures, a warpage of the device 12 is reduced or eliminated. Also, because of the presence of the epoxy 18, the solder balls 16 are able to flex, which reduces thermo-mechanical stresses in the device 12. Because the warpage of the device 12 is reduced or eliminated, corner-bonding is not required for the BGA package 10. Additionally, because warpage is reduced or eliminated, underfilling is not required for the BGA package 10, which is advantageous because the BGA 14 can be reworked much more easily compared to BGA packages that contain underfilling.

FIG. 3 is a flow chart diagram 30 showing a process for assembling, for example, the BGA package 10. A plurality of inputs are provided at box 32 and may include a substrate, such as a printed circuit board, epoxy-containing solder or epoxy-containing solder balls, and one or more components, such as an integrated circuit. A positioning step at box 34 positions the substrate, the epoxy-containing solder or the epoxy-containing solder balls, and the one or more components in a desired configuration. For example, epoxy-containing solder or epoxy-containing solder balls may be positioned to extend from the underside of one or more components to form a BGA, and the BGA may be placed on top of a substrate, such as the PCB 20 or the pads 22 of the PCB 20. A reflow step at box 36 applies heat to the inputs to reach an elevated temperature. As shown, the elevated temperature may be 200° C. or less than 200° C. In another embodiment, the elevated temperature may be a temperature between 140° C. and 190° C. After the reflow step, a connected BGA package is complete. Because of the epoxy-containing solder or epoxy-containing solder balls and because of the lower reflow temperatures that are required, the connected BGA package has minimal thermal warping and does not require underfilling or corner bonding. Further, an electrically insulating outer layer of epoxy on each of the soldered connections in the connected BGA package facilitates producing a fine pitch BGA via the process. The fine pitch BGA is enabled because connections are electrically insulated, which prevents electrical shorts from occurring. The connected BGA package may also be reworked, i.e., may be reprocessed if, for example, it does not meet product specifications.

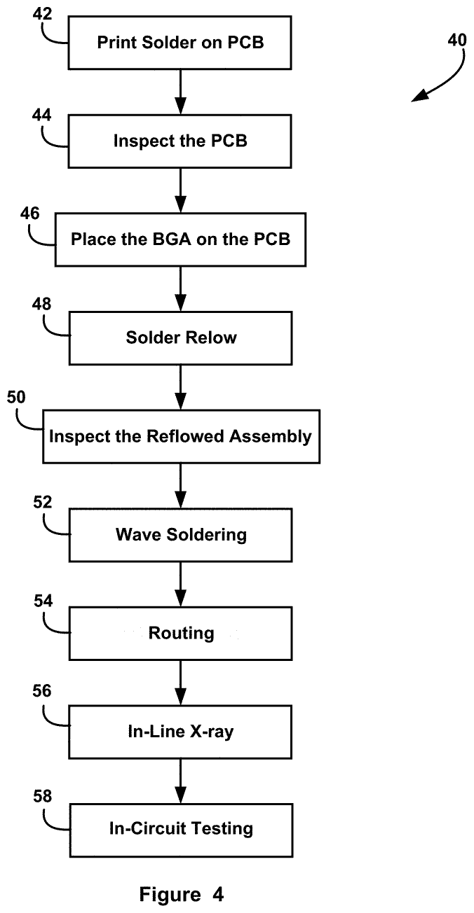

FIG. 4 shows a flow chart diagram 40 for a BGA process. In a step at box 42, solder is printed on a printed circuit board, where an epoxy-containing solder as disclosed herein may be used. In a step at box 44, the PCB 20 and the solder paste are inspected. In a step at box 46, a BGA including at least one component having at least one of the epoxy-containing solder balls 16 extending from an underside of the device 12 is placed on the PCB 20 in a pick and place step. In a step at box 48, the solder is reflowed at a temperature that may be less than 200° C. or may be reflowed at a temperature between 140° C. and 190° C. In a step at box 50, the reflowed assembly is inspected using, for example, an automated optical inspection. A wave soldering step is performed at box 52, if needed, and includes a bulk soldering process that is mainly used in soldering of through hole components in the manufacture of PCBs. A wave solder machine is required to perform this process, where the circuit board passes over molten solder. A routing step is performed at box 54, if needed, sometimes referred to as de-paneling. Routing is a process for removing numerous smaller individual PCBs from a larger multi-PCB panel. Routing was created in order to increase throughput of PCB manufacturing lines as the circuit board sized became smaller and smaller. An in-line X-ray step is performed on the BGA assembly at box 56, which is an X-ray inspection process after the wave soldering process that provides a high speed, solder coverage test for hidden joints. BGA, QFN and PTH barrel fill items are generally inspected during the X-ray inspection process based on the IPC acceptance criteria. An in-circuit test for electrical testing is performed at box 58.

In the foregoing detailed description, it may be that various features are grouped together in individual embodiments for the purpose of brevity in the disclosure. This method of the disclosure is not to be interpreted as reflecting an intention that any subsequently claimed embodiments require more features than are expressly recited.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

1. A ball grid array (BGA) package comprising:
at least one device; and
a BGA including a plurality of solder balls, where each solder ball is a combined mixture of a solder material and an electrically insulating epoxy and where the mixture of the solder material and the epoxy is formed through the entire solder ball, said solder balls being directly connected to the at least one device.

2. The BGA package of claim 1, wherein the plurality of solder balls become molten at a temperature less than 200 degrees Celsius.

3. The BGA package of claim 1, wherein the plurality of solder balls become molten at a temperature ≥140 degrees Celsius and ≤190 degrees Celsius.

4. (canceled)

5. (canceled)

6. The BGA package of claim 1, wherein the solder material is a tin-bismuth based solder.

7. The BGA package of claim 1, wherein the solder balls further include a self-aligning solder.

8. The BGA package of claim 1, wherein a distance between a center of one solder ball and a center of an adjacent solder ball is equal to or less than 0.5 millimeters.

9. The BGA package of claim 1, wherein a distance between a center of one solder ball and a center of an adjacent solder ball is greater than 0.5 millimeters.

10. The BGA package of claim 1, wherein a distance between a center of one solder ball and a center of an adjacent second solder ball is ≥0.2 mm and ≤1.00 mm.

11. The BGA package of claim 1, wherein a distance between a center of one solder ball and a center of another solder ball is equal to or less than 0.5 millimeters and a distance between the center of the one solder ball and a center of a third solder ball is greater than 0.5 millimeters.

12. The BGA package of claim 1, wherein the at least one device is an integrated circuit.

13. (canceled)

14. (canceled)

15. A method for producing a ball grid array (BGA) package, said method comprising:
providing a BGA including a plurality of solder balls where each solder ball is a combined mixture of a solder material and an electrically insulating epoxy and where the mixture of the solder material and the epoxy is formed through the entire solder ball;
positioning the BGA on a printed circuit board; and
applying heat to reflow the plurality of solder balls and to create a connection between the BGA and the printed circuit board.

16. The method of claim 15, wherein the heat is applied to achieve a solder ball reflow temperature of up to 200 degrees Celsius.

17. The method of claim 15, wherein the heat is applied to achieve a temperature of the solder ball reflow temperature 140 degrees Celsius and 190 degrees Celsius.

18. (canceled)

19. The method of claim 15, wherein warpage of a component disposed on the plurality of solder balls is minimized to such an extent that underfill is not required.

20. The method of claim 15, wherein warpage of a component disposed on the plurality of solder balls is minimized to such an extent that corner bonding is not required.
